(19) United States
(12) Patent Application Publication
(10) Pub. No.: US 2019/0096763 A1
(43) Pub. Date: Mar. 28, 2019

(54) LASER PROCESSING METHOD

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Mie MATSUO, Kamakura Kanagawa (JP)

(21) Appl. No.: 15/906,575

(22) Filed: Feb. 27, 2018

(30) Foreign Application Priority Data
Sep. 22, 2017 (JP) 2017-181998

(51) Int. Cl. H01L 21/78; H01L 21/268; H01L 21/67

(52) U.S. Cl. CPC H01L 21/78; H01L 21/67092; H01L 21/2686

(57) ABSTRACT

According to one embodiment, a laser processing method includes irradiating a region of a substrate with first laser light having a first pulse width greater than ten nanoseconds and irradiating the region substrate with second laser light having a second pulse width less than the first pulse width. In some embodiments, the region may be irradiated with the first and second laser lights simultaneously. In other embodiments, the irradiation with first laser light may occur before the irradiation with the second laser light.

### CROSS-REFERENCE TO RELATED APPLICATION

This application is based upon and claims the benefit of priority from Japanese Patent Application No. 2017-181998, filed Sep. 22, 2017, the entire contents of which are incorporated herein by reference.

### FIELD

Embodiments described herein relate generally to a laser processing method.

### BACKGROUND

In a semiconductor device manufacturing process, a semiconductor substrate is divided into a plurality of regions by division along so called dicing lines on a front surface of the semiconductor substrate, generally in a grid pattern, and semiconductor devices, often referred to as chips, are between the dicing lines.

The semiconductor substrate is cut (diced) along the dicing lines, whereby the circuit regions on the substrate are separated from one another for manufacture as individual semiconductor devices.

### DESCRIPTION OF THE DRAWINGS

FIG. 1 depicts parts of a processing apparatus according to a first embodiment.

FIG. 2 depicts a to-be-processed substrate before processing by a laser processing method according to the first embodiment.

FIG. 3 illustrates a state in which a tape has been attached to a dicing frame for holding a to-be-processed substrate according to the first embodiment.

FIG. 4 illustrates a state in which the to-be-processed substrate is being held in the dicing frame according to the first embodiment.

FIG. 5 illustrates timing sequences of first laser light and second laser light in a laser processing method according to the first embodiment.

FIG. 6 depicts parts of a processing apparatus according to a second embodiment.

FIG. 7 illustrates timing sequences of the first laser light and the second laser light in a laser processing method according to the second embodiment.

FIG. 8 illustrates timing sequences of the first laser light and the second laser light in a laser processing method according to another aspect of the second embodiment.

### DETAILED DESCRIPTION

An example embodiment provides a laser processing method for dicing semiconductor substrates.

In general, according to one embodiment, a laser processing method includes: irradiating a region of a substrate with first laser light having a first pulse width greater than ten nanoseconds and irradiating the region of the substrate with second laser light having a second pulse width less than the first pulse width.

Embodiments will be described hereinafter with reference to the drawings. In the drawings, the repeated aspects are denoted by the same reference signs.

### First Embodiment

A laser processing method according to a first embodiment for dicing or cutting a substrate includes: irradiating the substrate with first laser light having a first pulse width greater than ten nanoseconds; and irradiating the substrate with second laser light having a second pulse width smaller than the first pulse width.

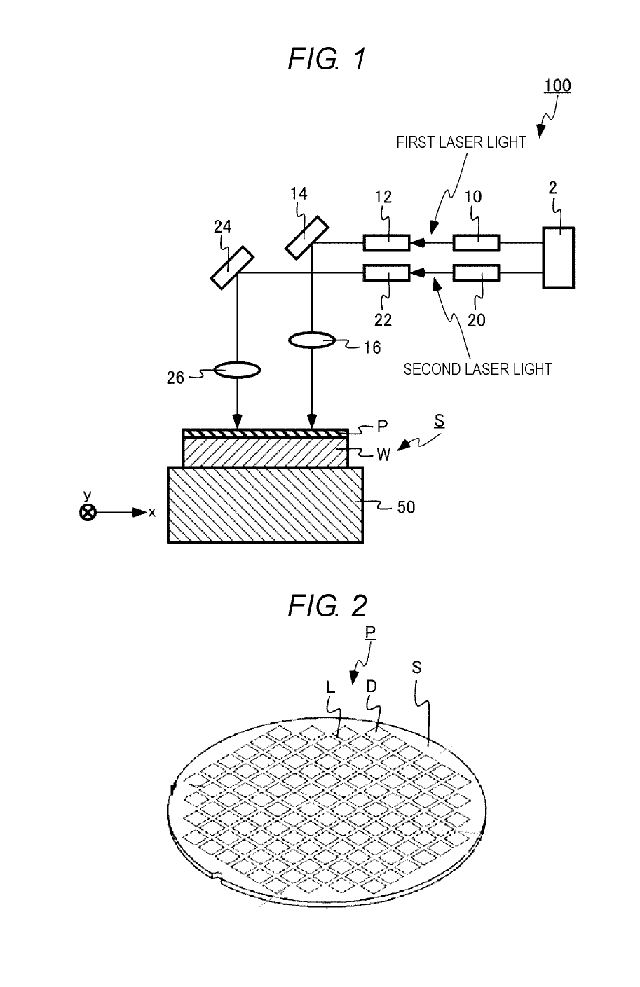

FIG. 1 depicts certain parts of a processing apparatus 100 according to the first embodiment. A processing apparatus according to the first embodiment is a laser processing apparatus for processing a substrate in an initially undiced state. FIG. 1 shows a configuration of a laser beam irradiation unit in the processing apparatus according to the first embodiment.

The processing apparatus 100 includes a control mechanism 2; a first laser oscillator 10; a first laser power adjustment unit 12; a first laser optical mirror 14; a first condenser lens 16; a second laser oscillator 20; a second laser power adjustment unit 22; a second laser optical mirror 24; a second condenser lens 26; and a stage 50.

Examples of a substrate S that can be processed include a Si (silicon) substrate, a SiC (silicon carbide) substrate, a GaN (gallium nitride) substrate, a lithium tantalum oxide (lithium tantalate) substrate, a lithium niobium oxide (lithium niobate) substrate, a sapphire substrate, a glass substrate, a quartz substrate, and a multilayer substrate of these substrates. The substrate S is, for example, a semiconductor substrate W, such as a wafer substrate.

The substrate S may comprise a semiconductor substrate W with a to-be-processed layer P formed on the semiconductor substrate W. The to-be-processed layer P includes, for example, integrated circuit devices and dicing lines that serve as inter-device separation regions.

The first laser oscillator 10 outputs first laser light. The second laser oscillator 20 outputs second laser light.

The first laser oscillator 10 and the second laser oscillator 20 are each a solid-state laser oscillator such as a YAG (yttrium-aluminum-garnet) laser oscillator or a YVO₄ laser oscillator, a gas laser oscillator, such as an excimer laser oscillator or a CO₂ laser oscillator, a semiconductor laser oscillator, or the like. Types of the first laser oscillator 10 and the second laser oscillator 20 are selected, as appropriate, depending on optical properties and a required quality of a to-be-processed material.

The first laser light and the second laser light each have a wavelength selected from wavelength ranges of ultraviolet light, visible light, and infrared light regions. Here, the wavelength range of ultraviolet light can be taken as between 100 nm and 400 nm. The wavelength range of visible light can be taken as between 360 nm and 830 nm. The wavelength range of infrared light can be taken as between 0.7 μm and 1 mm. The above stated wavelength ranges are endpoint inclusive.

The first laser power adjustment unit 12 is a structure that adjusts power of the first laser light radiated from the first laser oscillator 10. The second laser power adjustment unit 22 is a structure that adjusts power of the second laser light radiated from the second laser oscillator 20.

The first laser optical mirror 14 changes a path of the first laser light after the first laser light has been adjusted by the first laser power adjustment unit 12. The second laser optical mirror 24 changes a path of the second laser light after the second laser light has been adjusted by the second laser power adjustment unit 22.

The first condenser lens 16 focuses the first laser light on the substrate S. The first condenser lens 16 is after the first laser optical mirror 14 in the optical path of the first laser light. The second condenser lens 26 focuses the second laser light on the substrate S. The second condenser lens 26 is after the second laser optical mirror 24 in the optical path of the second laser light.

The control mechanism 2 controls output and irradiation timing of the first laser light output from the first laser oscillator 10 and the second laser light output from the second laser oscillator 20.

The control mechanism 2 may be hardware, such as an electrical circuit or a quantum circuit, or may be implemented in software. When the control mechanism 2 is implemented in software, a microprocessor with a CPU (Central Processing Unit) as a core, a ROM (Read Only Memory) that stores a processing program, a RAM (Random Access Memory) that temporarily stores data, input/output ports, and a communication port may be used as the control mechanism 2. A recording medium storing the software is not limited to a removable recording medium such as a magnetic disk or an optical disk but may be a fixed recording medium such as a hard disk apparatus or a non-volatile memory.

The substrate S is mounted on the stage 50. The stage 50 is movable to meet the irradiation timing of the first laser light and the second laser light in an X direction and a Y direction that are lateral directions orthogonal to each other by, for example, a motor that is not shown.

FIG. 2 depicts a substrate S that can be processed by a laser processing method according to the first embodiment.

The to-be-processed layer P includes devices D and dicing lines L. The devices D are, for example, integrated circuits. The dicing lines L formed between the devices D are to be irradiated with laser light during the dicing of the devices D. Examples of a material constituting the devices D include metals, silicon oxides, silicon nitrides, organic layers, and the like.

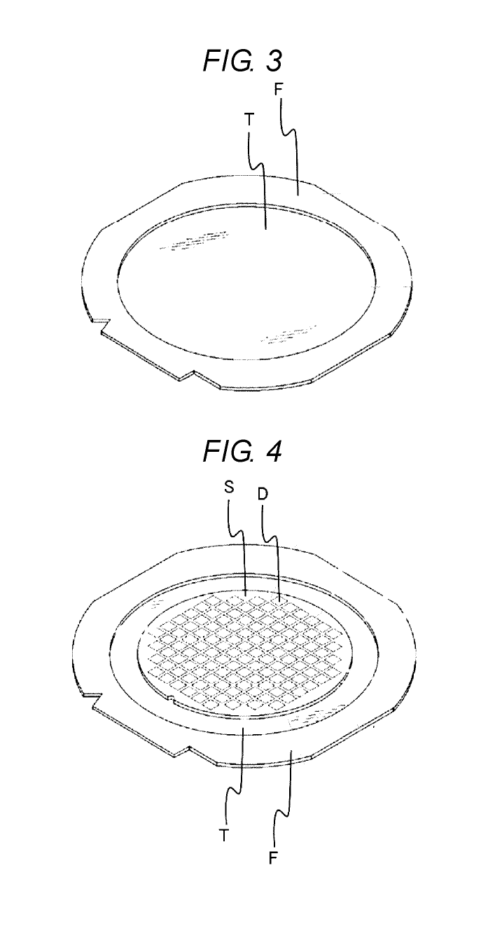

FIG. 3 illustrates a dicing tape T attached to a dicing frame F for holding the substrate S.

The devices D that have been diced by the laser light are held after dicing by the dicing tape T. The dicing frame F is an annular dicing frame.

FIG. 4 illustrates a substrate S being held in the dicing frame F. By irradiating the substrate S with the laser light while the substrate S is fixed to the dicing frame F by the dicing tape T, it is possible to control a processing position and a processing width of substrate S.

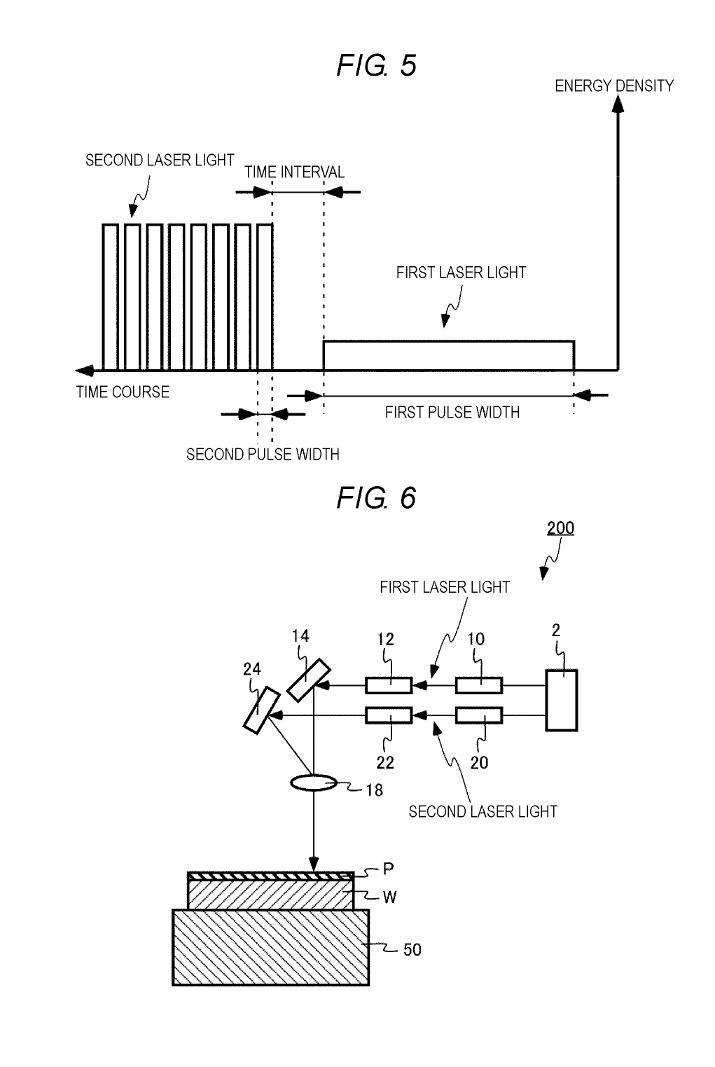

FIG. 5 temporal sequences of the first laser light and the second laser light in a laser processing method according to the first embodiment. Note that time course in FIG. 5 proceeds along a direction from page right to page left.

First, the substrate S is irradiated with the first laser light having a pulse width (a first pulse width) greater than ten nanoseconds. A pulse width equal to or greater than ten nanoseconds is selected because of the need to increase a temperature in a part of the substrate S being processed. When a pulse width less than ten nanometers was used, a phenomenon in which interatomic bonds of a constituent material were cleaved and sublimation of the material was observed before the temperature of the part being processed increased sufficiently.

Next, irradiation of the first laser light is stopped.

The substrate S is then irradiated with the second laser light having a pulse width (a second pulse width) smaller than the first pulse width (the pulse width of the first laser light). The substrate S is thereby subjected to laser ablation processing.

It is noted that the sequence of laser light irradiations described above may be repeated a plurality of times.

It is particularly preferable that the second pulse width (the pulse width of the second laser light) is between one femtosecond and one nanosecond in length.

Furthermore, it is preferable that a time interval (t₁) between the first laser light exposure and the second laser light exposure is less than the first pulse width.

Moreover, it is preferable that the number of pulses of the first laser light in the irradiation sequence is less than the number of pulses of the second laser light in the irradiation sequence.

It is also preferable that an energy density per unit time of the first laser light is lower than an energy density per unit time of the second laser light.

When laser-processed grooves are being formed by irradiating the substrate S with a pulsed laser beam for ablation processing, a pulse repetition frequency can be increased or the energy density of the laser light can be increased to improve processing efficiency.

However, heat is stored in the portions of the substrate S that have been irradiated with the laser light, disadvantageously generating cracking and reducing a strength of the resultant, post-dice chips. In addition, generation of edge chipping causes a decline in a quality of the fabricated devices. Furthermore, an oxide (debris) may be generated on a front surface (exposed surface) of the substrate S.

In the laser processing method according to the first embodiment, the substrate S is irradiated with a first laser light having a pulse width greater than ten nanoseconds, and then the substrate S is irradiated with a second laser light having a pulse width smaller than the first laser light pulse width.

Since the pulse width of the first laser light is greater than ten nanoseconds, it is possible to heat the substrate S. On the other hand, since the pulse width of the second laser light is small, bonds between atoms of the substrate S can be cleaved by irradiating the portions of the substrate S that has been heated by the first laser light with the second laser light. It is thereby possible to provide a laser processing method capable of preventing generation of cracking and chipping while improving processing efficiency.

The second pulse width (second laser light pulse width) is particularly preferably to be equal to or greater than one femtosecond and equal to or smaller than one nanosecond in order to cleave the interatomic bonds.

It is preferable that the first laser light and the second laser light each have a wavelength selected from wavelengths of ultraviolet light, visible light, and infrared light. The wavelength of the first laser light and that of the second laser light are selected, as appropriate, depending on the type of the to-be-processed substrate S.

It is preferable that the time interval t₁ between the first laser light and the second laser light is less than the first pulse width. When the time interval t₁ is greater than the first pulse width, portions of the substrate S that have just been irradiated with the first laser light may be cooled. As a result, even if the substrate S is irradiated with the second laser light, the cleavage of the bonds between the atoms constituting the substrate S may not be possible in the now cooled portions.

It is preferable that the number of pulses of the first laser light is less than the number of pulses of the second laser light. In other words, it is preferable that the number of pulses of the second laser light is greater than the number of pulses of the first laser light. This arrangement can make cleavage of atomic bonds in the substrate S more likely.

It is preferable that the energy density per unit time of the first laser light is lower than the second energy density per unit time of the second laser light. When the first laser light energy density is higher than the second laser light energy density, the processing is performed by the heat generated in the substrate S by the first laser light, resulting in the generation of cracking, chipping or debris.

According to the first embodiment, it is possible to provide a laser processing method with improved processing efficiency.

### Second Embodiment

A laser processing method according to a second embodiment differs from the laser processing method according to the first embodiment in that the substrate is irradiated with the first laser light and the second laser light simultaneously.

FIG. 6 depicts a processing apparatus 200 according to the second embodiment. The processing apparatus 200 differs from the processing apparatus 100 in that the first laser optical mirror 14, the second laser optical mirror 24 are adjusted such that lasers are routed to a condenser lens 18, and the optical path of the laser lights is changed so that the substrate S can be simultaneously irradiated with the first laser light and the second laser light at in the region being processed (diced).

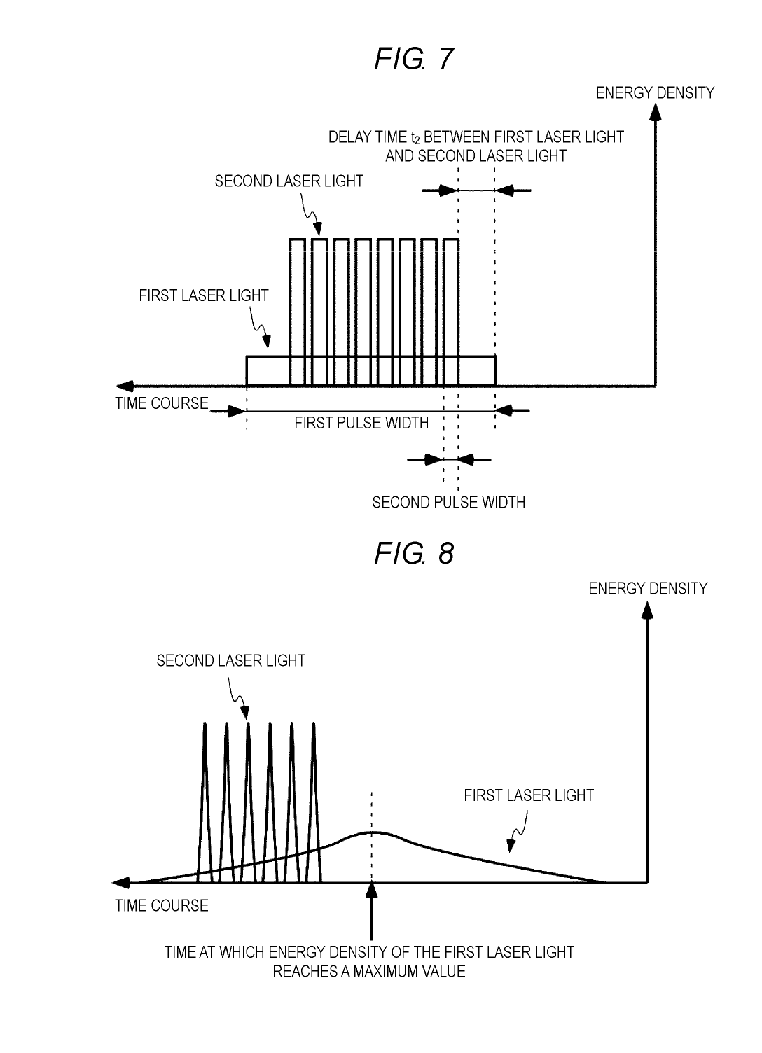

FIG. 7 illustrates timing sequences for the first laser light and the second laser light in a laser processing method according to the second embodiment. Note that time course in FIG. 7 proceeds along a direction from page right to page left.

With the laser processing method according to the second embodiment, a temperature of the region (s) being processed is increased to cause the temperature of at least a part of the processed regions to exceed a melting point and to liquefy the part by energy of the first laser light. Owing to this, it is possible to reduce reflectance in the regions being processed and to thereby facilitate processing by the second laser light.

Delay time t₂ between the start of first laser light pulse until the start of the second laser light pulses is preferably less than the second pulse width. In other words, it is preferable that after passage of a delay time t₂, that is greater than the second pulse width, from the start of irradiation with the first laser light, the second laser light pulses are started and the thus the substrate S is irradiated simultaneously with the first and second laser lights. The reason for this preference is as follows. If the delay time t₂ is too short, the temperature of the regions being processed does not sufficiently increase and the interatomic bonds cannot be sufficiently cleaved by the second laser light.

FIG. 8 illustrates a temporal sequencing of the first laser light and the second laser light in a laser processing method according to another example of the second embodiment. Note that time course in FIG. 8 proceeds along a direction from page right to page left.

An energy density of laser light increases over time after irradiation starts. The energy density of the laser light then decreases over time after reaching a maximum value.

It is preferable that the second laser light is applied to the substrate after the energy density of the first laser light reaches its maximum value. The reason is as follows. The temperature of the regions being processed does not sufficiently increase before the energy density of the first laser light reaches the maximum value. As a result, the interatomic bonds cannot be sufficiently cleaved by the second laser light.

According to the second embodiment, it is possible to provide the laser processing method capable of improving processing efficiency.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate dicing method, comprising:
irradiating a region of a substrate with a first laser light having a pulse width greater than ten nanoseconds; and
irradiating the region of the substrate with a second laser light having a pulse width less than the pulse width of the first laser light.

2. The substrate dicing method according to claim 1, wherein the first laser light and the second laser light each have a wavelength in a wavelength range selected from the ultraviolet range, the visible range, and the infrared range.

3. The substrate dicing method according to claim 1, wherein a time interval between the irradiating with the first laser light and the irradiating with the second laser light is less than the pulse width of the first laser light.

4. The substrate dicing method according to claim 1, wherein the irradiating with the first laser light and the irradiating with the second laser light occur at a same time.

5. The substrate dicing method according to claim 4, wherein the irradiating with the second laser light begins after passage of a delay time from a start of the irradiating with the first laser light, and the delay time is greater than the pulse width of the second laser light.

6. The substrate dicing method according to claim 4, wherein an energy density of the first laser light reaches a maximum value before the irradiating with the second laser light begins.

7. The substrate dicing method according to claim 1, wherein a number of pulses of the first laser light provided to the region per unit time is less than a number of pulses of the second laser light provided to the region per unit time.

8. The substrate dicing method according to claim 1, wherein an energy density of the first laser light per unit time is less than an energy density of the second laser light per unit time.

9. The substrate dicing method according to claim 1, wherein the substrate includes a semiconductor substrate and a device layer formed on the semiconductor substrate.

10. A substrate dicing apparatus, comprising:
a stage upon which a substrate frame can be disposed, the substrate frame configured to hold a substrate for dicing;
a first laser oscillator configured to output a first laser light;
a second laser oscillator configured to output a second laser light;
an optics system by which a region of the substrate in the dicing frame on the stage can be irradiated with the first laser light and the second laser light, wherein
the first laser light has a pulse width greater than ten nanoseconds, and
the second laser light has a pulse width less than the pulse width of the first laser light.

11. The substrate dicing apparatus according to claim 10, wherein the pulse width of the second laser light is less than one nanosecond in length and greater than one femtosecond in length.

12. The substrate dicing apparatus according to claim 10, wherein the optics system includes:
a first condenser lens for the first laser light; and
a second condenser lens for the second laser light.

13. The substrate dicing apparatus according to claim 10, wherein the optics system includes:
a condenser lens through which both the first and second laser lights pass.

14. The substrate dicing apparatus according to claim 10, wherein the stage is moveable in an X-Y plane parallel to an upper surface of the substrate.

15. The substrate dicing apparatus according to claim 10, further comprising:
a controller connected to the first and second laser oscillators and configured to control the first and second laser oscillators to irradiate the region of the substrate with first and second laser lights at a same time.

16. The substrate dicing apparatus according to claim 10, further comprising:
a controller connected to the first and second laser oscillators and configured to control the first laser oscillator to irradiate the region of the substrate with first laser light and to control the second laser oscillator to irradiate the region of the substrate with second laser light after the first laser light.

17. A method of dicing a semiconductor wafer, comprising:
exposing a region of a semiconductor wafer between two die formed on the semiconductor wafer to a first laser light having a pulse width greater than ten nanoseconds;
exposing the region to a second laser light having a pulse width greater than one femtosecond and less than one nanosecond; and
separating the two die from each other after exposing the region to first and second laser lights.

18. The method of claim 17, wherein the region is exposed to the first and second laser lights simultaneously.

19. The method of claim 17, wherein the region is exposed to first laser light, then exposed to the second laser light, and a time interval between exposures is less than the pulse width of the first laser light.

20. The method of claim 17, wherein the first laser light has an energy density which varies during the exposing of the region, and the exposing of the region to the second laser light occurs at a same time as the exposing of the region to the first laser later but after a maximum energy density of the first laser light has been reached.
